(19) United States
(12) Patent Application Publication
(10) Pub. No.: US 2007/0281631 A1
(43) Pub. Date: Dec. 6, 2007

(54) Arrangement for transmitting signals via an antenna feed line in a mobile radio subscriber station

(76) Inventor: Helmut Nast, Berlin (DE)

Correspondence Address: Frank J. Bonini, Jr.;86 The Commons at Valley Forge East, 1288 Valley Forge Road, Post Office Box 750, Valley Forge, PA, 19482-0750, US

(21) Appl. No.: 11/796,571

(22) Filed: Apr. 27, 2007

(30) Foreign Application Priority Data
May 4, 2006 (DE) 10 2006 021 514.1

(51) Int. Cl. H04B 1/034; H03C 1/52; H04B 1/02

(52) U.S. Cl. 455/99; 455/108; 455/114.2

(57) ABSTRACT

The invention relates to an arrangement for transmitting signals via an antenna feed line in a mobile subscriber station, particularly in a vehicle, such as, for example, a road motor vehicle, whereby the arrangement has an antenna feed line and a signal amplifier to amplify the signals. It is proposed to set the overall amplification of the signals which are transmitted between an external antenna of the mobile subscriber station and a mobile subscriber device (95) and/or vice versa depending on a connection attenuation which is produced by connecting the mobile subscriber device (95) to the antenna feed line (setting device 37, 73). The connection can be established in particular in a wireless manner via an antenna coupler (93) which is disposed in an electromagnetically screening housing to accommodate the subscriber device.

The invention relates to an arrangement for transmitting signals via an antenna feed line in a mobile radio subscriber station, particularly in a vehicle, such as, for example, a road motor vehicle.

Numerous holders are already known with which a mobile telephone can be held in a required position inside a motor vehicle. In most cases, connections for the electrical connection of the mobile telephone to a hands-free installation and/or to an antenna of the motor vehicle are integrated in the holders. However, it is also known for the mobile telephone to be connectable via a Bluetooth radio interface to the hands-free installation built into the motor vehicle.

However, the holders are normally suitable only for mobile telephones with a specific structural shape. If a different type of mobile telephone is to be mounted, a new holder or at least a new adapter is normally required.

The overall attenuation of the signals which are transmitted via the antenna feed line depends on the type of holder and the type of connection of the mobile telephone to the external antenna of the motor vehicle. There are, for example, mobile telephones with an electrical connection via which the mobile telephone can be connected to the antenna feed line. In this case, the connection attenuation (i.e. the attenuation caused by the connection of the mobile telephone to the antenna feed line) is low. However, there are also mobile telephones without such an antenna connection. In this case, the mobile telephone can be connected via an antenna coupler to the antenna feed line. This results, for example, in a connection attenuation in the order of magnitude of 6 dB.

An object of the present invention is to indicate an arrangement which is suitable for the connection of a multiplicity of different mobile telephone types and/or the connection according to different connection types.

A mobile telephone is understood to mean any type of terminal device which can be operated in a mobile network. The mobile telephone does not need, in particular, to be able to transmit and as well to receive signals.

The mobile subscriber station, in particular the inner space of the vehicle, should preferably be shielded against radio signals which the mobile telephone emits.

An electromagnetically shielding housing which, for example, is permanently installed within the interior of the motor vehicle, can be provided for this purpose. An electrical connection to connect the mobile telephone to the antenna feed line can be provided in the housing. However, an antenna coupler is preferably provided, via which the mobile telephone can be connected to the antenna feed line without an electrical line. The housing can accommodate mobile telephones with different external dimensions. As a result, the handling of the mobile telephone when connecting it to the antenna feed line is significantly simplified and different mobile telephone types can be accommodated by the same housing.

In particular, the connection to the antenna feed line can also be established indirectly via a radio interface which does not serve to transmit the antenna signals which are transmitted by the mobile telephone when the mobile telephone is operated directly in the mobile network. A radio interface of this type corresponds, for example, to the Bluetooth standard. The mobile telephone can be connected via the radio interface, for example, to a hands-free installation which performs the function of the terminal device for operation on the mobile network. For example, following the connection of the mobile telephone, the information required for this operation, in particular SIM card data, is transferred from the mobile telephone onto the hands-free installation.

In this description, the term electromagnetically shielding is understood to mean that the amplitude of electromagnetic waves that are about to penetrate housing components is significantly reduced. In a particular design, the electromagnetic screening is specifically designed for one or more of the frequency bands in which mobile telephones transmit and/or receive their radio signals. This may involve the frequency bands that are used within a mobile telephone network and/or the frequency bands for an additional radio interface, for example according to the Bluetooth standard.

According to a further aspect of the invention, at least one signal amplifier is provided to amplify the signals which are transmitted via the antenna feed line in the mobile subscriber station. In this way, signal levels reduced as a result of the attenuation, in particular the connection attenuation, can be raised (amplified). The signal amplifier can essentially be disposed here at any point on the antenna feed line. For example, a first signal amplifier can be disposed in the vicinity of the mobile telephone to amplify the signals which are to be transmitted by the mobile subscriber station so that the signals amplified by it are transmitted at least via the predominant part of the antenna feed line to the antenna of the subscriber station (and can in turn be attenuated). If an electromagnetically shielding housing is provided to accommodate the mobile telephone, the first signal amplifier is preferably disposed in or on the housing. In particular, the housing and the first signal amplifier may form one structural unit, i.e. they are mechanically interconnected.

Furthermore, a second signal amplifier can be provided which amplifies the signal received by the antenna of the subscriber station, so that the amplified signals can be transmitted via the antenna feed line, or at least a substantial part thereof, to the mobile telephone.

When a transmission of signals via the antenna feed line to the mobile telephone is mentioned in this description, this is also understood to include the case in which the mobile telephone is connected to equipment of the mobile subscriber station, but this equipment (for example a hands-free installation) has taken over essential functions for operation on the mobile network.

According to a particularly preferred embodiment of the invention, a setting device is provided for setting an overall amplification of the signals which are transmitted between an external antenna of the mobile subscriber station and a mobile subscriber device (the mobile telephone) and/or vice versa. The setting device is designed to set the overall amplification depending on a connection attenuation produced by connecting the mobile subscriber device to the antenna feed line.

This reveals the underlying problem outlined above, according to which different mobile telephones can be connected in different ways to the antenna feed line, whereby different connection attenuations can arise.

The setting device can act on the signal amplifier(s) and directly set the amplification. However, in a preferred design, the setting device alternatively or additionally has a settable attenuation device which is connected to the antenna feed line in such a way that signals transmitted via the antenna feed line are attenuated according to a set attenuation, i.e. in particular the signal level is reduced.

For example, the amplification of the signal amplifier(s) is selected in such a way that it is also sufficient in the case where the maximum possible connection attenuation occurs. The signal level can then be set to a required value or within a required range of values by setting the attenuation caused by the attenuation device. A zero attenuation setting is also possible.

According to a further concept of the invention, a detection device can be provided which is connected to the antenna feed line and which is designed to evaluate signals transmitted via the antenna feed line and to detect a setting value to which the setting device is to be set. This enables the signals transmitted via the antenna feed line to be designed in such a way that, in particular, the information relating to the existing connection attenuation or the selected connection type and/or mobile telephone type is contained in the signals. If, for example, a mobile telephone is connected to the antenna feed line (electrically or via the antenna coupler), the corresponding information relating to the connection attenuation can be transmitted automatically via the antenna feed line to the detection device.

The detection device is preferably connected to the setting device and/or combined with the latter, and is designed to set the setting device according to the detected setting value. Various options can be considered for transmitting the information relating to the setting value of the setting device via the antenna feed line. In particular, a frequency signal can be generated (for example a sinusoidal frequency signal with a preferably temporally constant frequency in the 20 to 30 kHz range), which is superimposed over the actual signals to be transmitted via the antenna feed line. Alternatively or additionally, the superimposed signal can be injected into the antenna feed line by applying a DC voltage to the antenna feed line (in particular to the central conductor of a coaxial cable against ground).

In more general terms, a signal-generating device is preferably provided which is connected to the antenna feed line and is designed to generate a signal which is transmitted via the antenna feed line to the detection device and which contains information indicating the setting value to which the setting device is to be set.

The signal-generating device has, for example, a frequency generator which is designed to generate a frequency signal which is superimposed over the signals to be transmitted via the antenna feed line.

Furthermore, the scope of the invention includes a system with an arrangement in one of the embodiments described in this description, and with a plurality of signal-generating devices which can in each case generate a signal to set the setting device to a setting value allocated to the signal-generating device, whereby one or more of the signal-generating devices can be built into the arrangement and/or one or more of the signal-generating devices which are built into the arrangement can be activated and de-activated.

The system enables mobile telephones of different types to be connected and/or to be connected in different ways to an arrangement with an antenna feed line, and in each case to set an overall amplification which is the same or which lies within a defined level range. In a specific example of the arrangement, a plurality of the signal-generating devices can be provided which are, for example, in each case designed according to one of a plurality of connection devices for connection of a subscriber terminal device to the arrangement. Alternatively or additionally, at least one signal-generating device can be selected from the system and provided as part of a specific arrangement. In particular, it is therefore possible to design different specimens of the arrangement by providing different signal-generating devices according to the respective possible or available connection types for subscriber terminal devices as part of the arrangement.

Moreover, the scope of the invention also includes a method for transmitting signals via an antenna feed line in a mobile subscriber station, particularly in a vehicle, such as, for example, a road motor vehicle, whereby an overall amplification of the signals which are transmitted between an external antenna of the mobile subscriber station and a mobile subscriber device and/or vice versa is set automatically depending on a connection attenuation which is produced by connecting the mobile subscriber device to the antenna feed line.

Reference is also made to the description of the different embodiments of the arrangement according to the invention with regard to the advantages and variants of the method. Embodiments of the method are, in particular, also the subject-matter of the dependent subclaims.

Further features of the invention, which may optionally be provided in addition to the features already mentioned, along with exemplary embodiments of the invention, will now be described with reference to the attached drawing. In the individual figures of the drawing:

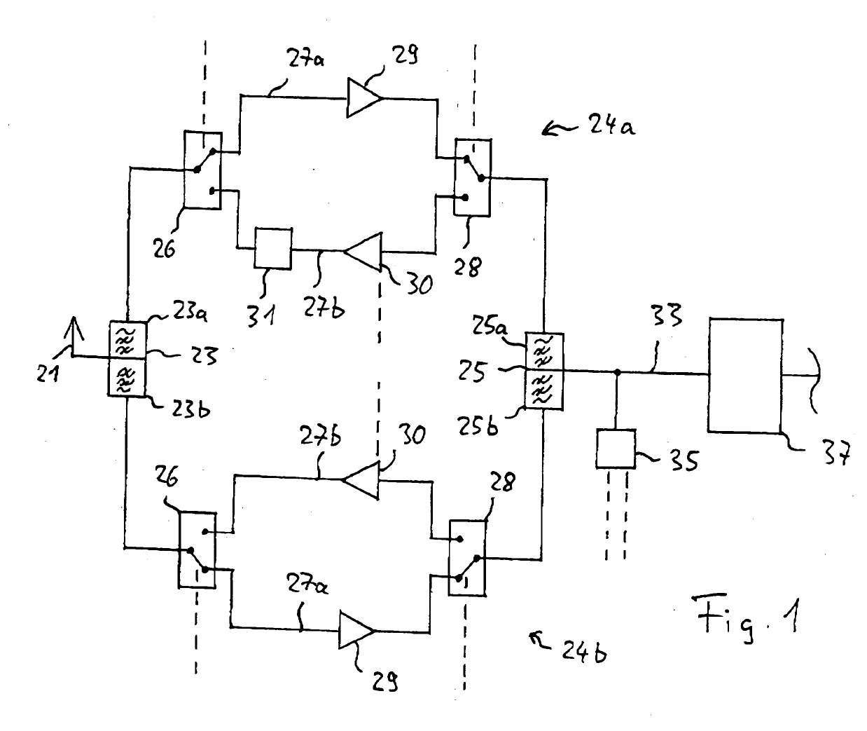

FIG. 1 shows a part of a first design form of an arrangement for transmitting signals via an antenna feed line in a mobile subscriber station,

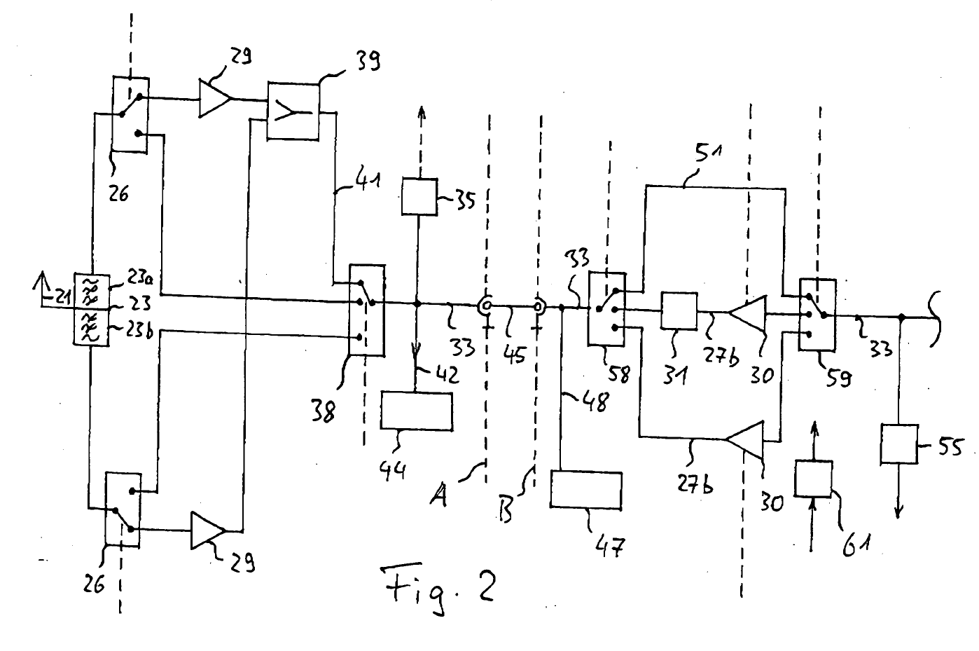

FIG. 2 shows a second design form of an arrangement of this type,

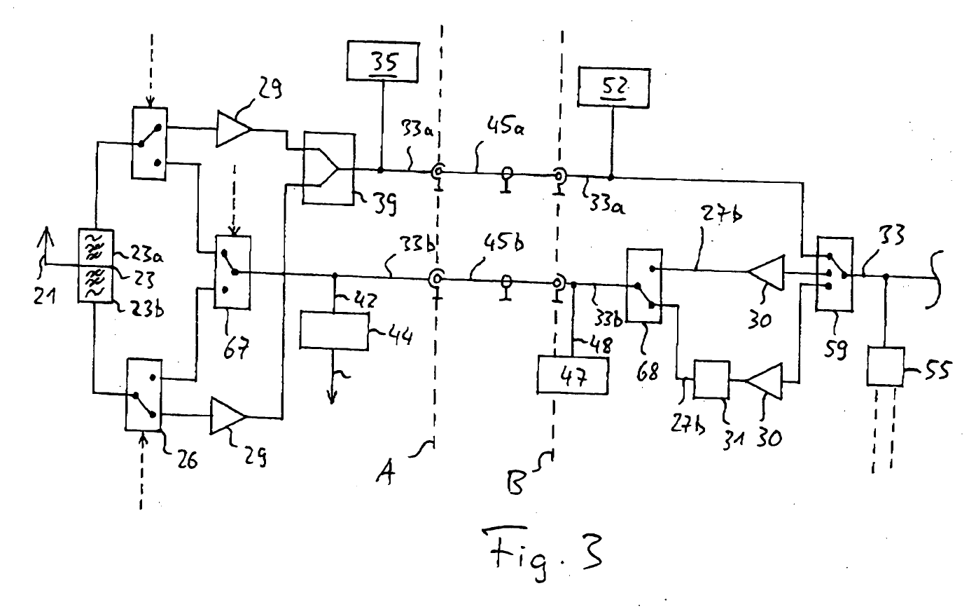

FIG. 3 shows a third design form of an arrangement of this type,

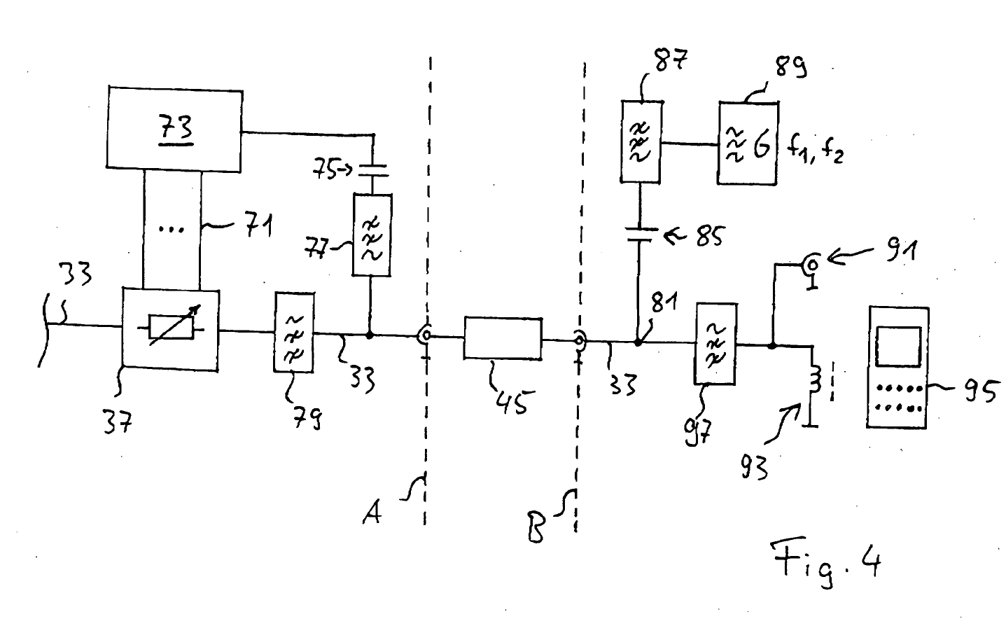

FIG. 4 shows a detail of a design form which can optionally be combined with one of the design forms shown in FIG. 1 to 3, and

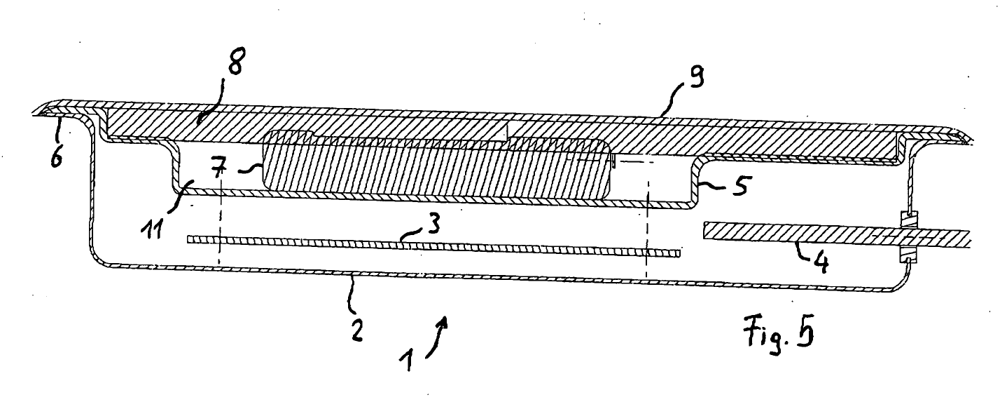

FIG. 5 shows a vertical longitudinal section through a housing with a mobile telephone disposed therein.

FIG. 1 shows the circuit diagram of an arrangement which is integrated, for example, into a road motor vehicle. An external antenna of the mobile subscriber station is designated by 21. An external antenna is understood to mean an antenna for transmitting and/or receiving radio signals to or from the outside of the subscriber station, whereby the radio signals are transmitted within a mobile network. The antenna 21 is connected to a diplexer 23, which has a high-pass filter 23a and a low-pass filter 23b. The diplexer 23 serves to enable operation of the arrangement for the transmission of signals in different frequency ranges, e.g. in the frequency range of the GSM1800 mobile standard and also the GSM900 mobile standard. Instead of the diplexer, a frequency separating filter for a different number of frequency bands can also be provided, so that the arrangement (this also applies to the arrangements shown in FIG. 2 and FIG. 3) is also suitable e.g. for a UMTS mobile network.

The arrangement shown in FIG. 1 has a second diplexer 25 with a high-pass filter 25a and a low-pass filter 25b. Two branches 24a, 24b of the antenna feed line, which are in each case connected at one of their ends to the low-pass filter 23b and the low-pass filter 25b (in the case of the branch 24b) or to the high-pass filter 23a and the high-pass filter 25a (in the case of the branch 24a), are disposed between the first diplexer 23 and the second diplexer 25. The two branches 24a, 24b are essentially of identical design, and for this reason the same reference symbols are used in FIG. 1 for elements of the two branches 24a, 24b. A switch 26, 28, which serves to switch over the signal path in each case to one of two sub-branches 27a, 27b is connected directly via a section of the antenna feed line. The switch may in each case be e.g. an SPDT analog switch (Single-Pole/Double-Throw analog switch). As shown in each case by a broken line in FIG. 1, the switching condition of the switches 26, 28 is controlled via a signal line.

In the switching condition shown in FIG. 1, switchover has taken place in each case to the sub-branch 27a, which has a second signal amplifier 29 to amplify the signals which have been received by the antenna 21 and are transmitted via the antenna feed line. The second amplifier 29 is e.g. an LNA (Low Noise Amplifier). Since the signals received via the antenna 21 may in some instances be very weak signals, i.e. signals with a high noise component, it is preferred that the second signal amplifier 29 is connected via a shortest possible path of the antenna feed line to the antenna 21. It is particularly preferred that the diplexer 23 (or a different frequency separating filter), the switch 26 and furthermore at least the second signal amplifier 29 are integrated into the antenna base of the antenna. An antenna base is understood to mean the mechanical part of an antenna arrangement with which the antenna is mechanically attached to the mobile subscriber station.

Alternatively, the aforementioned part of the arrangement can also be disposed outside the antenna base, but in the immediate vicinity of the antenna base. In particular, the length of the path of the antenna feed line from the antenna base to the second signal amplifier is a maximum of 1.5 m, preferably a maximum of 30 cm.

In the design form shown in FIG. 1, the entire part of the arrangement shown is preferably located in the antenna base or in the vicinity of the antenna base. With reference to FIG. 2, a further different arrangement is described which has fewer components and can therefore be more easily integrated into the antenna base.

In the arrangement shown in FIG. 1, the second sub-branch 27b has a first signal amplifier 30, which serves to amplify signals which are to be transmitted to the antenna 21 and from the antenna 21 into the mobile network. The first signal amplifier is in particular a power amplifier, with which the signals to be transmitted can be adequately amplified to enable them to be transmitted in the mobile network.

Only in the first branch 24a, a harmonic filter 31, which has a low-pass effect, is connected in series with the first signal amplifier 30.

From the perspective of the antenna 21 beyond the diplexer 25, a part of the antenna feed line begins, via which all signals which are to be transmitted via the antenna feed line between the subscriber terminal device and the antenna 21 are transmitted (common path 33). A detector 35 is connected to the common path 33. As shown by two broken lines which begin at the detector 35, the latter is connected to the switches 26, 28 via signal lines, so that the switch settings of the switches 26, 28 can be controlled by the detector 35 depending on the signals on the common path 33. Moreover, the detector 35 is connected via the signal lines to the power amplifiers 30. It is therefore also able to control the transmission power of the power amplifiers 30. In particular, the, detector can detect control signals which are transmitted via the common path 33, and can control the switches and/or amplifiers depending thereon.

Furthermore, a digitally settable attenuation component 37 is located on the common path 33, the attenuation of which can be set by a device which is not shown in FIG. 1. A device of this type is described with reference to FIG. 4.

The design form according to FIG. 2 will now be described. However, only those parts of the arrangement in which the arrangement differs from the arrangement shown in FIG. 1 will be described. Identical and functionally identical elements and devices are designated with the same reference symbols as in FIG. 1. The same applies to FIG. 3, which has still to be described.

Leaving the antenna 21, the received signals in turn reach the diplexer 23. However, instead of the second diplexer 25, a switch 38 is provided which is directly connected to the switch 26 for the signals which are to be transmitted via the antenna 21. The switch 38 may, for example, be a 3:1 multiplexer, in particular a Single-Pole/Triple-Throw analog switch (SP3T). On the path of the signals received by the antenna 21 from the switch 26 in the direction of the subscriber terminal device, a second signal amplifier 29, the output of which is connected to a combining device 39 which combines the output signals of the amplifiers 29 again onto a common path 41 of the received signals, is in each case located in the arrangement for the frequency bands. The combining device 39 may, for example, be a diplexer. An output of the combining device 39 is connected via the common path 41 of the reception signals to a connection of the switch 38.

A part of the common path 33 of all signals to be transmitted via the antenna feed line begins at the switch 38, to which the detector 35 is in turn connected to control the switches 26, 38. However, in this case the detector 35 does not control the power amplifiers.

Furthermore, a line 42, via which electrical current can be extracted, i.e. branched off, from the common path 33 in order to supply power, in particular, to the amplifiers 29, is also connected to the common path 33. The devices which are to be supplied with electrical power via this extracted current are shown schematically by the block designated with reference number 44. The block 44 also contains further power supply elements.

A power supply of this type via the common path 33 can also be provided in other design forms of the invention. It is particularly advantageous if the components, elements and devices to be supplied with power are disposed in an area that is not easily accessible. In the case of the exemplary embodiment shown in FIG. 2, all elements and devices to the left of the vertical broken line designated by A form part of an antenna arrangement, whereby (with the exception of the antenna 21 itself) all other elements and devices can be integrated, in particular, into the antenna base. Since this part of the overall arrangement, in contrast to FIG. 1, also contains the power amplifiers, the integration into the antenna base and/or elsewhere in miniaturized form can be achieved all the more easily.

FIG. 2 furthermore shows a coaxial cable 45 which can be designed in practice as very much longer compared with the other line paths shown and, for example, connects the antenna arrangement at the rear of a road motor vehicle (e.g. an automobile) to the remainder of the arrangement in the middle or front area of the vehicle. This remainder is partially shown in FIG. 2 to the right of the vertical broken line designated by the reference letter B. The part shows a device 47 which is connected via a line 48 to the common path 33 and which serves to inject electrical current, which is extracted via the line 42. The common path 33 is connected to a second 3-way switch 58. This may in turn involve a 3:1 multiplexer, in particular an SP3T. One of the three connections of the switch 58 to which the signal flow of the common path 33 can be switched over is connected via a continuous line connection 51 to a corresponding connection of a further switch 59, which in turn may be a 3:1 multiplexer, e.g. an SP3T. This line connection 51 serves to transmit control signals via the common path 33 in the area B, the coaxial cable 45 and the other part of the common path 33 in the antenna arrangement (area A). In particular, these control signals can be used by the detector 35 to control the switches 26, 38 and/or the amplifier power of the amplifiers 29.

Furthermore, the sub-branches 27b, which correspond to the sub-branches 27b shown in FIG. 1 and which have power amplifiers 30, are disposed between the switches 58, 59. From the perspective of the sub-branches 27b beyond the switch 59, a further section of the common path 33 is located, to which a further detector 55 is connected to control the switching conditions of the switches 58, 59 and the amplifier power of the power amplifiers 30. Moreover, the remaining part of the overall arrangement (not shown in FIG. 2) is connected to this part of the common path 33. This remaining part has, for example (with the exception of the coaxial cable shown there) elements and devices which will be described with reference to FIG. 4. This includes in particular the settable attenuation component 37 with the associated setting device, a connection device to connect the arrangement to a subscriber terminal device, the signal generation to transmit the setting signals for the setting device via the antenna feed line and the signal recognition.

FIG. 2 furthermore shows a power supply device 61 which, for example, in a road motor vehicle, symbolizes the on-board power supply to supply consumers with electrical power. The device 61 is connected to the device 47 to inject the current into the common path 33.

FIG. 3 shows a modification of the arrangement shown in FIG. 2, whereby the essential difference is that, instead of the one coaxial cable 45 for transmission of both the transmission signals (i.e. to transmit from the antenna 21 into the mobile network) and the reception signals (i.e. the signals which have been received by the antenna 21), two coaxial cables (or other line connections) 45a, 45b are provided for separate transmission of the signals in the transmission direction and the reception direction. Instead of the switch 38 in FIG. 2, a switch 67 is provided in the antenna arrangement, which may be a 2:1 multiplexer, in particular an SPDT. The common path 33b for the transmission signals which is connected to this switch 67 is routed via the coaxial cable 45b to a switch 68 in the remote part of the arrangement (in area B). On this switch 68, the signal path is again split into the sub-branches 27b, which are brought together again on a further switch 59 to form a common path 33 for all signals of the antenna feed line. The signal path for the transmission signals has been described against the signal flow direction.

Since the reception signals are not brought together again on a 3-way switch with the reception signals as shown in FIG. 2, the output of the combining device 39 is connected via a common path 33a, which is a common path only for the reception signals, and via a coaxial cable 45a to the remote part of the arrangement. There, the common path 33a ends on the switch 59 and merges once more with the common path 33 of all signals.

A device 52 for injecting control signals in the remote part of the arrangement onto the common path 33a is shown on the top right in FIG. 3. The control signals injected in this way can be extracted by the detector 35 of the antenna arrangement from the common path 33a.

The part of the arrangement now described with reference to FIG. 4 can be combined without modification with the part of the arrangement described in FIG. 1, whereby the digitally settable attenuation component 37 is shown in both FIG. 1 and FIG. 4. The part of the arrangement shown in FIG. 1 with the exception of the attenuation component 37 starts in FIG. 4 on the left on the common path 33.

The attenuation component 37 is connected via a control line 71, which, for example, can transmit digital signals with a resolution of 5 bits, to a detection device 73. The detection device 73 is designed to transmit, via the control signal line 71, control signals to set the attenuation level of the attenuation device 37. The detection device 73 has, for example, a ROM (Read Only Memory). An input of the detection device 73 is connected via a series connection comprising a direct-current blocking device 75 (with e.g. a capacitor) and a low-pass filter 77 to the common path 33 of the antenna feed line. One variant of this part of the arrangement, which can be connected to the arrangement shown in FIG. 3, may also entail, rather than the common path 33 for all signals, the common path 33a for the reception signals and/or the common path 33b for all transmission signals.

In the specific design shown in FIG. 4, in which the detection device is controlled via frequency signals, a high-pass filter 79 is furthermore disposed on the common path 33, in a section between the subscriber terminal device and the attenuation device 37, between the connection point of the series connection 75, 77 and the attenuation device 37. In this way, the detection device 73 can be controlled via frequency signals which have a low frequency compared with the actual signals to be transmitted. In particular, the detection device 73 can set the corresponding attenuation level of the attenuation device 37 depending on the frequency of these low-frequency signals. The correspondences between the respective low frequency and the bit value to be transmitted via the signal line 71 are, for example, stored in the ROM for this purpose.

In the exemplary embodiment shown in FIG. 4, the attenuation component and the previously described parts of the arrangement (to the left of the vertical broken line designated as A) form part of the antenna arrangement. This part is connected via a coaxial cable 45 to the (from the perspective of the antenna) remote part of the arrangement. There, the common path 33 is connected via a connection point 81 with a second series connection comprising a direct-current blocking device 85 and a low-pass filter 87 to a frequency generator 89. FIG. 4 indicates by means of the symbols f₁, f₂ that the frequency generator 89 can generate signals of different frequencies. Here, the frequency generator 89 preferably always generates only one frequency signal at a given time and the frequency of this signal is constant through time and changes only if the connection attenuation has changed. This is, for example, the case if a mobile telephone is connected to the antenna feed line in a different manner and/or a different mobile telephone is connected to the antenna feed line.

Instead of a single frequency generator 89, a plurality of frequency generators can also be provided or can optionally form part of the arrangement. For example, each of the frequency generators is set to a fixed frequency. The frequency generator which is provided in each case for a specific connection attenuation or which can be selected is activated or connected to the arrangement only if a subscriber terminal device is connected to the antenna feed line with this connection attenuation. For example, a motor vehicle may have an electrical connection via which antenna signals of a mobile telephone can be injected or extracted directly and essentially without attenuation losses. Moreover, the vehicle may have a housing in which a terminal device can be accommodated, and can be connected to the antenna feed line in a wireless manner via an antenna coupler disposed in the housing. In this case, a frequency generator, which is preferably activated automatically when the terminal device is connected, can be provided in each case for both the electrical connection and the housing.

In the specific exemplary embodiment shown in FIG. 4, the electrical connection is designated by the reference number 91 and the antenna coupler is designated by the reference number 93. The terminal device, in this case a mobile telephone, is designated by the reference number 95. A second high-pass filter 97 is disposed between the contact point 81 for the branch of the frequency generator and the connection for the terminal device.

However, the invention is not limited to this combination of connection types. A different signal generating device, which generates, for example, a DC voltage signal, can also be provided instead of the frequency generator 89.

Furthermore, the part of the arrangement which serves to amplify the transmitter signals can be integrated into the electromagnetically screening housing. This includes in particular the power amplifier or the power amplifiers for different frequency bands. In the design shown in FIG. 2 or FIG. 3, this may also include the switches 58 and 59 or 68 and 59.

In contrast to FIG. 1 to FIG. 3, the amplifiers for the transmission signals or for the reception signals can also be replaced by a single amplifier which carries out the amplification for different frequency bands. The amplifier can be set to the frequency band used.

As shown in FIG. 5, in one design of the arrangement according to the invention, a housing 1 can be provided which has an underpart 2 and a cover 9. The underpart 2 surrounds an inner space of the housing 1 on all sides with the exception of the upper side. The underpart 2 is essentially designed as cuboid, but has rounded corners and forms an upper edge 6 to support a trough-shaped insert part 5. The underpart 2 is made e.g. of metal (and can optionally be connected to the ground potential of the motor vehicle), so that it attenuates electromagnetic waves which penetrate the underpart 2 and/or so that electromagnetic waves cannot penetrate the underpart 2. In both cases, a shielding effect is achieved.

The trough-shaped insert 5 defines a partial inner space 11 inside the housing 1, which is large enough in each case to dispose a mobile telephone therein, whereby the mobile telephone can be selected from a large number of different types, whereby the external dimensions of the mobile telephones may vary within a wide range. In particular, the length of the mobile telephone 7 extending from right to left in FIG. 1 does not completely fill the partial inner space 11. In particular, there would still be space for an antenna projecting upwards (i.e. pointing to the right in FIG. 5) on the mobile telephone 7 or on a different mobile telephone.

The insert 5 forms a shoulder, i.e. an area to the side of the partial inner space 11, in which it extends above the level of the support surface for the mobile telephone 7 in roughly a horizontal direction. From this level, the material of the insert 5 then rises to the level of the edge 6 of the underpart 2. In the closed condition of the housing 1 shown in FIG. 5, a foam plastic panel 8, which can be attached on the underside of the cover 9, is laid on the aforementioned intermediate level. The height or thickness of the foam plastic panel 8 is dimensioned in such a way that it extends from the lower surface of the cover 9 up to the intermediate level, where it lies on the shoulder of the insert 5. Furthermore, the height of the insert 5 in the area of the partial inner space 11 in which the mobile telephone 7 or other mobile telephones can be disposed is dimensioned in such a way that the thickness in the case of mobile telephones with a thickness in the normal range (the thickness is the dimension which extends in the vertical direction in FIG. 5) is greater than the height between the support surface for the mobile telephone 7 and the upper edge of the shoulder. In this way, the mobile telephone projects beyond the level of the shoulder and therefore presses the foam plastic panel 8 onto the mobile telephone when the cover 9 is closed, as shown in FIG. 1 and FIG. 2. The foam plastic of the foam plastic panel 8 is therefore squeezed (not shown in FIG. 1 and FIG. 2) and, due to the resulting elastic deformation, exerts a contact pressure on the mobile telephone 7 which, together with its weight, presses the mobile telephone onto the support surface of the insert 5.

The foam plastic panel 8 is made from a material which causes high dielectric losses in the event of penetrating electromagnetic waves, in particular in the frequency ranges used by mobile telephones, so that the waves are attenuated and a shielding effect is achieved. Carbon, for example, which causes the substantial part of the dielectric losses, is distributed in the foam plastic material. The foam plastic material may, for example, be polyurethane foam.

Suitable foam plastics with an electromagnetic screening effect are sold, for example, by Emc-Technik und Consulting GmbH, Emilienstraβe 35, 70563 Stuttgart. The homogeneous attenuation foam from Emc GmbH, known as C-RAM MT, for example, can be used for the exemplary embodiment shown in FIG. 5.

A board 3 is disposed in the space between the floor of the underpart 2 and the partial inner space 11 (trough) in which the mobile telephone 7 is disposed. Electrical components, circuit elements and further devices can be fitted to the board 3. Furthermore, a different body which carries devices of this type can be provided instead of a board. These devices can, in particular, perform functions which serve to operate the mobile telephone 7 or a different mobile telephone in the housing 1 or in a different housing. In particular, the devices can be fitted to the board 3 or to the different body as an antenna structure, so that radio signals can be transmitted between the antenna structure and the antenna of the mobile telephone. The antenna structure is in turn connected via a lead through 4 through the housing to the antenna feed line of the vehicle antenna. Further devices, such as, for example, a first signal amplifier and/or a second antenna structure for a Bluetooth interface can similarly be provided between the mobile telephone and the devices on the board 3 or on the other body. For example, the mobile telephone can therefore be connected in a manner known per se via the Bluetooth interface to a hands-free device of the motor vehicle with at least one loudspeaker and with at least one microphone. A suitable arrangement for signal amplification is described, for example, in DE 10114531.

What is claimed is:

1. An arrangement for transmitting signals via an antenna feed line in a mobile subscriber station, particularly in a vehicle, such as, for example, a road motor vehicle, wherein the arrangement comprises the following:
the antenna feed line,
a signal amplifier (29, 30) to amplify the signals.

2. The arrangement as claimed in the preceding claim, whereby the arrangement has a setting device (37, 73) for setting an overall amplification of the signals which are transmitted between an external antenna of the mobile subscriber station and a mobile subscriber device and/or vice versa, whereby the setting device (37, 73) is designed to set the overall amplification depending on a connection attenuation produced by connecting the mobile subscriber device to the antenna feed line.

3. The arrangement as claimed in the preceding claim, wherein the setting device (37, 73) comprises a settable attenuation device (37) which is connected to the antenna feed line in such a way that signals transmitted via the antenna feed line are attenuated according to a set attenuation.

4. The arrangement of claim 2, wherein the arrangement comprises a detection device (73) which is connected to the antenna feed line and which is designed to evaluate signals transmitted via the antenna feed line and to detect a setting value to which the setting device (37, 73) is to be set.

5. The arrangement as claimed in the preceding claim, wherein the detection device (73) is connected to and/or combined with the setting device (37, 73), and is designed to set the setting device (37, 73) according to the detected setting value.

6. The arrangement of claim 5, the arrangement comprising at least one signal-generating device which is connected to the antenna feed line and is designed to generate a signal which is transmitted via the antenna feed line to the detection device (73) and contains information indicating the setting value to which the setting device (37, 73) is to be set.

7. The arrangement as claimed in the preceding claim, wherein the signal-generating device has a frequency generator (89) which is designed to generate a frequency signal which is superimposed over the signals to be transmitted via the antenna feed line.

8. A system comprising the arrangement of claim 6 and comprising a plurality of the signal-generating devices which can in each case generate a signal to set the setting device to a setting value allocated to the signal-generating device, wherein one or more of the signal-generating devices, which can be built into the arrangement, and/or one or more of the signal-generating devices which are built into the arrangement can be activated and de-activated.

9. The arrangement of claim 1, wherein the antenna feed line is connected to an antenna coupler (93) which is disposed within an electromagnetically shielding housing to accommodate a mobile telephone and is designed to transmit signals of the antenna feed line in a wireless manner to an antenna of the mobile telephone (95) and/or to receive signals transmitted by an antenna of the mobile telephone (95).

10. A method for transmitting signals via an antenna feed line in a mobile subscriber station, particularly in a vehicle, such as, for example, a road motor vehicle, wherein an overall amplification of the signals which are transmitted between an external antenna of the mobile subscriber station and a mobile subscriber device and/or vice versa is set automatically depending on a connection attenuation which is produced by connecting the mobile subscriber device to the antenna feed line.

11. The method as claimed in the preceding claim, wherein an attenuation value of a settable attenuation device (37) is set in order to set the overall amplification.

12. The method of claim 10, wherein information indicating the setting value to which a setting device (37, 73) should be set in order to set the overall amplification is transmitted via the antenna feed line or via a part of the antenna feed line.

13. The method as claimed in the preceding claim, wherein a signal for transmitting the information is a frequency signal which is superimposed over the signals to be transmitted via the antenna feed line.

14. The method of claim 13, wherein the overall amplification is set depending on the manner in which the mobile subscriber device(s) is/are connected to the antenna feed line and/or whether the mobile subscriber device(s) is/are activated via the mobile subscriber device(s).

15. The arrangement of claim 3, wherein the arrangement comprises a detection device (73) which is connected to the antenna feed line and which is designed to evaluate signals transmitted via the antenna feed line and to detect a setting value to which the setting device (37, 73) is to be set.

16. The arrangement of claim 15, wherein the detection device (73) is connected to and/or combined with the setting device (37, 73), and is designed to set the setting device (37, 73) according to the detected setting value.

17. The arrangement of claim 4, the arrangement comprising at least one signal-generating device which is connected to the antenna feed line and is designed to generate a signal which is transmitted via the antenna feed line to the detection device (73) and contains information indicating the setting value to which the setting device (37, 73) is to be set.

18. The arrangement of claim 15, the arrangement comprising at least one signal-generating device which is connected to the antenna feed line and is designed to generate a signal which is transmitted via the antenna feed line to the detection device (73) and contains information indicating the setting value to which the setting device (37, 73) is to be set.

19. The arrangement of claim 15, wherein the signal-generating device has a frequency generator (89) which is designed to generate a frequency signal which is superimposed over the signals to be transmitted via the antenna feed line.

20. A system comprising the arrangement of claim 7 and comprising a plurality of the signal-generating devices which can in each case generate a signal to set the setting device to a setting value allocated to the signal-generating device, wherein one or more of the signal-generating devices, which can be built into the arrangement, and/or one or more of the signal-generating devices which are built into the arrangement can be activated and de-activated.

21. A system comprising the arrangement of claim 15 and comprising a plurality of the signal-generating devices which can in each case generate a signal to set the setting device to a setting value allocated to the signal-generating device, wherein one or more of the signal-generating devices, which can be built into the arrangement, and/or one or more of the signal-generating devices which are built into the arrangement can be activated and de-activated.

22. The arrangement of claim 8, wherein the antenna feed line is connected to an antenna coupler (93) which is disposed within an electromagnetically shielding housing to accommodate a mobile telephone and is designed to transmit signals of the antenna feed line in a wireless manner to an antenna of the mobile telephone (95) and/or to receive signals transmitted by an antenna of the mobile telephone (95).

23. The method of claim 11, wherein information indicating the setting value to which a setting device (37, 73) should be set in order to set the overall amplification is transmitted via the antenna feed line or via a part of the antenna feed line.

24. The method of claim 23, wherein a signal for transmitting the information is a frequency signal which is superimposed over the signals to be transmitted via the antenna feed line.

25. The method of claim 24, wherein the overall amplification is set depending on the manner in which the mobile subscriber device(s) is/are connected to the antenna feed line and/or whether the mobile subscriber device(s) is/are activated via the mobile subscriber device(s).
